(19) United States
(12) Patent Application Publication
(10) Pub. No.: US 2026/0282521 A1
(43) Pub. Date: Sep. 17, 2026

(54) SEMICONDUCTOR DEVICE

(71) Applicant: DENSO CORPORATION, Kariya-city (JP)

(72) Inventors: Hiroto SUGIURA, Kariya-city (JP); Masanori MIYATA, Kariya-city (JP)

(21) Appl. No.: 19/669,262

(22) Filed: May 6, 2026

Related U.S. Application Data
(63) Continuation of application No. PCT/JP2024/039181, filed on Nov. 4, 2024.

(30) Foreign Application Priority Data
Nov. 6, 2023 (JP) 2023-189327

(51) Int. Cl. H10D 84/00; H10D 8/00; H10D 12/00; H10D 62/10; H10D 62/60

(52) U.S. Cl. CPC H10D 84/161; H10D 8/422; H10D 12/481; H10D 62/126; H10D 62/60; H10D 12/415; H10D 62/107

(57) ABSTRACT

A semiconductor device includes a semiconductor substrate including a drift layer disposed in a cell region and a connection region, a base layer disposed in a surface portion of the drift layer in the cell region and the connection region, a collector layer disposed in IGBT regions and the connection region, and a cathode layer disposed in FWD regions. A surface of the semiconductor substrate adjacent to the base layer is defined as a first surface. The semiconductor device further includes a contact region disposed in a surface portion of the base layer in an additional FWD region and the connection region. On the first surface of the semiconductor substrate, a formation area of the contact region per unit area in the connection region is smaller than a formation area of the contact region per unit area in the additional FWD region.

### CROSS REFERENCE TO RELATED APPLICATIONS

The present application is a continuation application of International Patent Application No. PCT/JP2024/039181 filed on November 4, 2024, which designated the U.S. and claims the benefit of priority from Japanese Patent Application No. 2023-189327 filed on November 6, 2023. The entire disclosures of all of the above applications are incorporated herein by reference.

### TECHNICAL FIELD

The present disclosure relates to a semiconductor device in which an insulated gate bipolar transistor (hereinafter referred to as “IGBT”) element having an insulated gate structure and a free-wheel diode (hereinafter referred to as “FWD”) element are formed on a common semiconductor substrate.

### BACKGROUND

Conventionally, semiconductor devices have been proposed that include an IGBT region where an IGBT element is formed and an FWD region where an FWD element is formed.

### SUMMARY

A semiconductor device according to an aspect of the present disclosure includes a semiconductor substrate having a cell region and an outer peripheral region surrounding the cell region, insulated gate bipolar transistor (IGBT) regions disposed in the cell region and having IGBT elements, and free-wheel diode (FWD) regions disposed in the cell region and having FWD elements. The IGBT regions and the FWD regions are alternately arranged along one direction in a planar direction of the semiconductor substrate. The outer peripheral region includes a pad portion electrically connected to the IGBT elements. The pad portion is disposed at one end portion of the outer peripheral region in the one direction. The cell region may include, as the FWD regions, an inner FWD region sandwiched between the IGBT regions and an additional FWD region disposed on one side in an intersecting direction, which intersects with the one direction in the planar direction of the semiconductor substrate, relative to the pad portion. An end portion of the cell region adjacent to the pad portion in the one direction may include the additional FWD region. The outer peripheral region may include an inner edge region adjacent to the cell region and an outer edge region located opposite to the cell region across the inner edge region. The inner edge region may include a connection region located between the additional FWD region and the outer edge region. The semiconductor substrate may include a drift layer of a first conductivity type disposed in the cell region and the connection region, a base layer of a second conductivity type disposed in a surface portion of the drift layer in the cell region and the connection region, a collector layer of the second conductivity type disposed on a side of the drift layer opposite to the base layer in the IGBT regions and the connection region, and a cathode layer of the first conductivity type disposed on the side of the drift layer opposite to the base layer in the FWD regions. A surface of the semiconductor substrate adjacent to the base layer may be defined as a first surface, and a surface of the semiconductor substrate adjacent to the collector layer and the cathode layer may be defined as a second surface. The semiconductor device may further include a trench gate structure provided in the IGBT regions, the FWD regions, and the connection region, and including trenches extending deeper than the base layer into the drift layer, and a gate insulating film and a gate electrode disposed in the trenches, an emitter region of the first conductivity type disposed in a surface portion of the base layer in the IGBT regions, in contact with the trenches, and a contact region of the second conductivity type disposed in the surface portion of the base layer in the additional FWD region and the connection region and having a higher impurity concentration than the base layer. On the first surface of the semiconductor substrate, a formation area of the contact region per unit area in the connection region is smaller than a formation area of the contact region per unit area in the additional FWD region.

### BRIEF DESCRIPTION OF DRAWINGS

Objects, features and advantages of the present disclosure will become apparent from the following detailed description made with reference to the accompanying drawings. In the drawings:

FIG. 1 is a plan view of a semiconductor device according to a first embodiment;

FIG. 2 is a cross-sectional view of the semiconductor device taken along line II-II in FIG. 1;

FIG. 3 is a cross-sectional view of the semiconductor device taken along line III-III in FIG. 1;

FIG. 4 is a perspective cross-sectional view of an IGBT region;

FIG. 5 is an enlarged plan view of region V in FIG. 1;

FIG. 6 is a schematic diagram showing the flow of holes when an FWD element is in the ON state in the first embodiment;

FIG. 7 is a schematic diagram showing the flow of holes when an FWD element is in the ON state in a comparative example;

FIG. 8 is a diagram showing reverse current characteristics of the semiconductor device according to the first embodiment and a semiconductor device of the comparative example;

FIG. 9 is a diagram showing a relationship between a connection region width ratio and a recovery loss;

FIG. 10 is a plan view of a second surface side of an FWD region in a second embodiment;

FIG. 11A is a plan view of a second surface side of an FWD region in a modification of the second embodiment;

FIG. 11B is a plan view of a second surface side of an FWD region in another modification of the second embodiment;

FIG. 12 is a plan view of a semiconductor device according to a third embodiment;

FIG. 13 is a plan view of a semiconductor device according to a fourth embodiment; and

FIG. 14 is a cross-sectional view of the semiconductor device taken along line XIV-XIV in FIG. 13.

### DETAILED DESCRIPTION

Next, relevant technology is described to facilitate understanding of the following embodiments. A semiconductor device according to the relevant technology is configured to have a cell region and an outer peripheral region surrounding the cell region. The cell region includes a plurality of IGBT regions in which IGBT elements are formed and a plurality of FWD regions in which FWD elements are formed. In the outer peripheral region, elements such as a gate pad connected to gate electrodes of the IGBT elements are formed. Each of the IGBT elements is configured to include a base layer of P-type, a contact region of P⁺-type and an emitter region of N⁺-type formed in a surface portion of the base layer, and a trench gate structure formed so as to penetrate the base layer, the contact region, and the emitter region. Each of the FWD elements is configured to include a base layer of P-type, a contact region of P⁺-type formed in a surface portion of the base layer, and a trench gate structure formed so as to penetrate through the base layer and the contact region. In the above-described semiconductor device, each of the IGBT regions and each of the FWD regions are formed in a planar rectangular shape with one direction as a longitudinal direction, and along a transverse direction intersecting the longitudinal direction, the IGBT regions and FWD regions are arranged alternately. In the above-described semiconductor device, end portions in the transverse direction (that is, an arrangement direction) are IGBT regions. The pads are arranged in a portion located in the transverse direction relative to the cell region.

The present inventors have studied the following semiconductor device in order to suppress the occurrence of electric field concentration in the outer peripheral region in the above-described semiconductor device. That is, the present inventors have considered forming a deep layer of P⁺-type, which is connected to the base layer and has a higher impurity concentration than the base layer, in the outer peripheral region. However, if the deep layer is arranged close to the cell region, when the FWD elements are in the ON state, holes as carriers are likely to flow from the deep layer into the FWD elements, resulting in an increased reverse current and, consequently, a greater recovery loss. The present inventors have defined a region in the outer peripheral region located adjacent to the cell region as an inner edge region, and a region located on the opposite side of the cell region across the inner edge region as an outer edge region. Then, the present inventors have considered forming, in the inner edge region, a base layer, a contact region, and a trench gate structure similar to those in the cell region, and forming the deep layer in the outer edge region.

According to the above configuration, since the trench gate structure is also formed between the deep layer and the cell region, it is possible to suppress the occurrence of electric field concentration in the inner edge region.

Furthermore, in order to increase the cell region in the semiconductor device, the present inventors have considered arranging an additional FWD region adjacent to the pads. Hereinafter, an FWD region added next to the pads is also referred to as the additional FWD region. In the cell region of the above-described semiconductor device, the end portion adjacent to the pads in the transverse direction includes the additional FWD region.

However, in the semiconductor device having the additional FWD region, since the end portion adjacent to the pads in the transverse direction includes the additional FWD region, a region where the FWD region and the outer peripheral region are adjacent to each other increases. Therefore, in such a semiconductor device, when the FWD elements are in the ON state, an increased inflow of holes as carriers from the outer peripheral region may occur, potentially resulting in greater recovery loss.

A semiconductor device according to an aspect of the present disclosure includes a semiconductor substrate having a cell region and an outer peripheral region surrounding the cell region, insulated gate bipolar transistor (IGBT) regions disposed in the cell region and having IGBT elements, and free-wheel diode (FWD) regions disposed in the cell region and having FWD elements. The IGBT regions and the FWD regions are alternately arranged along one direction in a planar direction of the semiconductor substrate. The outer peripheral region includes a pad portion electrically connected to the IGBT elements, the pad portion being disposed at one end portion of the outer peripheral region in the one direction. The cell region includes, as the FWD regions, an inner FWD region sandwiched between the IGBT regions and an additional FWD region disposed on one side in an intersecting direction, which intersects with the one direction in the planar direction of the semiconductor substrate, relative to the pad portion, and an end portion of the cell region adjacent to the pad portion in the one direction includes the additional FWD region. The outer peripheral region includes an inner edge region adjacent to the cell region and an outer edge region located opposite to the cell region across the inner edge region. The inner edge region includes a connection region located between the additional FWD region and the outer edge region. The semiconductor substrate includes a drift layer of a first conductivity type disposed in the cell region and the connection region, a base layer of a second conductivity type disposed in a surface portion of the drift layer in the cell region and the connection region, a collector layer of the second conductivity type disposed on a side of the drift layer opposite to the base layer in the IGBT regions and the connection region, and a cathode layer of the first conductivity type disposed on the side of the drift layer opposite to the base layer in the FWD regions. A surface of the semiconductor substrate adjacent to the base layer is defined as a first surface, and a surface of the semiconductor substrate adjacent to the collector layer and the cathode layer is defined as a second surface. The semiconductor device further includes a trench gate structure provided in the IGBT regions, the FWD regions, and the connection region, and including trenches extending deeper than the base layer into the drift layer, and a gate insulating film and a gate electrode disposed in the trenches, an emitter region of the first conductivity type disposed in a surface portion of the base layer in the IGBT regions, in contact with the trenches, and a contact region of the second conductivity type disposed in the surface portion of the base layer in the additional FWD region and the connection region and having a higher impurity concentration than the base layer. On the first surface of the semiconductor substrate, a formation area of the contact region per unit area in the connection region is smaller than a formation area of the contact region per unit area in the additional FWD region.

According to this configuration, the connection region is configured such that the formation area of the contact region per unit area is smaller than the formation area of the contact region per unit area in the additional FWD region. Therefore, even in the semiconductor device having the additional FWD region, it is possible to suppress an increase in recovery loss.

Hereinafter, embodiments of the present disclosure will be described with reference to the drawings. In the following embodiments, the same or equivalent parts are denoted by the same reference numerals for description.

### First Embodiment

A first embodiment will be described with reference to the drawings. A semiconductor device according to the present embodiment is preferably used as a power switching element used in power supply circuits such as inverters and DC/DC converters, for example.

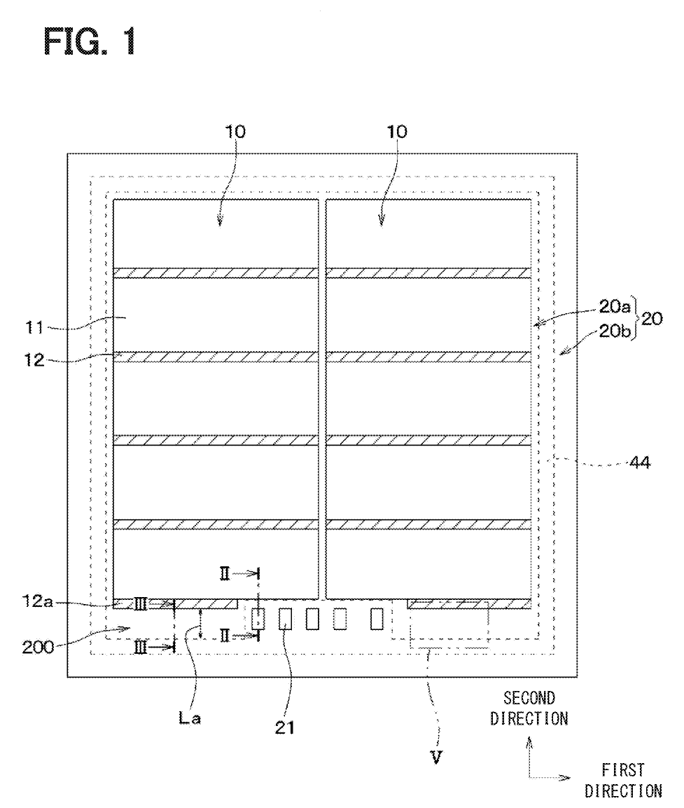

As shown in FIG. 1, the semiconductor device includes cell regions 10 and an outer peripheral region 20 surrounding the cell regions 10. First, a planar configuration of the semiconductor device according to the present embodiment will be described.

The cell region 10 is configured to include IGBT regions 11, in which IGBT elements are formed, and FWD regions 12, in which FWD elements are formed. In other words, the semiconductor device of the present embodiment is a reverse conducting (RC) IGBT, in which the IGBT regions 11 and the FWD regions 12 are formed within a common semiconductor substrate 30, as will be described later. Specifically, as will be described later, in the present embodiment, portions above collector layers 41, which are located on a second surface 30b of the semiconductor substrate 30, are defined as the IGBT regions 11, and portions above cathode layers 42, which are located on the second surface 30b of the semiconductor substrate 30, are defined as the FWD regions 12. Although FIG. 1 is not a cross-sectional view, the FWD regions 12 are hatched so as to make them easier to understand.

In the present embodiment, the IGBT region 11 and the FWD region 12 are formed so as to have portions that are alternately arranged along one direction within the cell region 10. In other words, the IGBT regions 11 and the FWD regions 12 are formed so as to have portions that are alternately arranged along one direction in a surface direction of the semiconductor substrate 30, which will be described later.

In the present embodiment, the IGBT regions 11 and the FWD regions 12 are each formed as rectangular regions having a longitudinal direction, and are alternately formed along a direction that intersects with the longitudinal direction. Hereinafter, the longitudinal direction of the IGBT regions 11 and the FWD regions 12 will be referred to as a first direction, and the direction that intersects with the first direction will be referred to as a second direction. In FIG. 1, the left-right direction on the page corresponds to the first direction, and the up-down direction on the page corresponds to the second direction. The second direction corresponds to one direction, and the first direction corresponds to an intersecting direction, which intersects with the one direction in the planar direction of the semiconductor substrate 30.

It should be noted that the second direction can be regarded as one direction in the planar direction of the semiconductor substrate 30, which will be described later, and the first direction can be regarded as a direction orthogonal to the second direction and as another direction along the planar direction of the semiconductor substrate 30, which will also be described later.

In the outer peripheral region 20, pad portions 21 are formed. The pad portions 21 are connected to gate electrodes 35 described later, a temperature sensing element (not shown), and the like. In the present embodiment, five pad portions 21 are arranged. The pad portions 21 are arranged along the first direction at one end portion in the second direction. Hereinafter, in a rectangular frame-shaped portion of the outer peripheral region 20 along the outer shape of the semiconductor device, a portion adjacent to the cell region 10 will be referred to as an inner edge region 20a, and a portion located opposite to the cell region 10 across the inner edge region 20a will be referred to as an outer edge region 20b. The pad portions 21 are arranged in the inner edge region 20a.

In the present embodiment, two cell regions 10 are arranged along the first direction, and the inner edge region 20a is formed as a rectangular frame-shaped portion surrounding the two cell regions 10. In each of the cell regions 10, five IGBT regions 11 are formed along the second direction. Furthermore, in each of the cell regions 10, each of the FWD regions 12 is formed between the adjacent IGBT regions 11 along the second direction. Furthermore, the FWD regions 12 are also formed at the one end portion in the second direction where the pad portions 21 are arranged, so as to be located in the first direction with respect to the pad portions 21. Hereinafter, the FWD regions 12 located at the one end portion in the second direction where the pad portions 21 are arranged also are referred to as the additional FWD regions 12a.

In the present embodiment, the additional FWD regions 12a in the respective cell regions 10 are formed so as to sandwich the pad portions 21 in the first direction. It should be noted that, in the cell regions 10, portions facing the pad portions 21 in the second direction are formed as the IGBT regions 11. In other words, the length of the additional FWD regions 12a in the first direction is set to be shorter than the length of the IGBT regions 11 or other FWD regions 12 in the first direction. Hereinafter, in the inner edge region 20a, portions located between the additional FWD regions 12a and the outer edge region 20b will be described as connection regions 200.

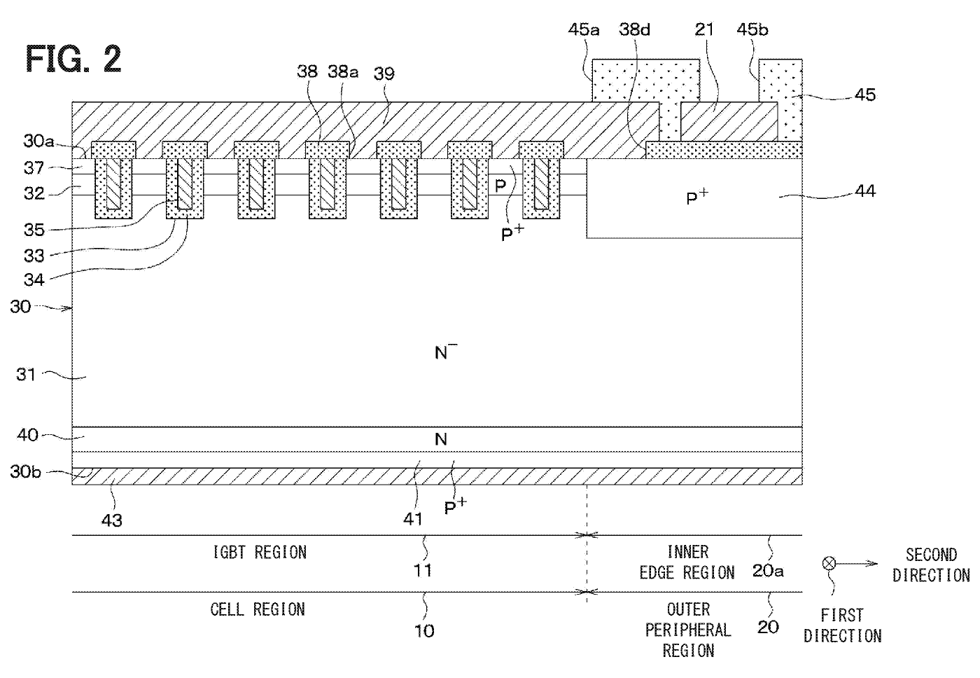

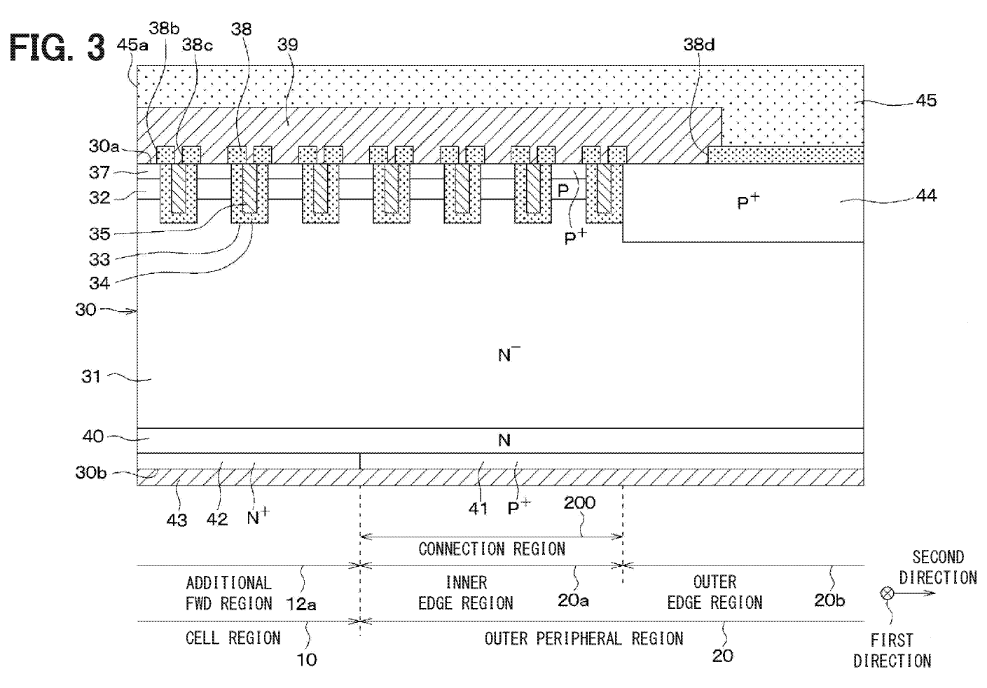

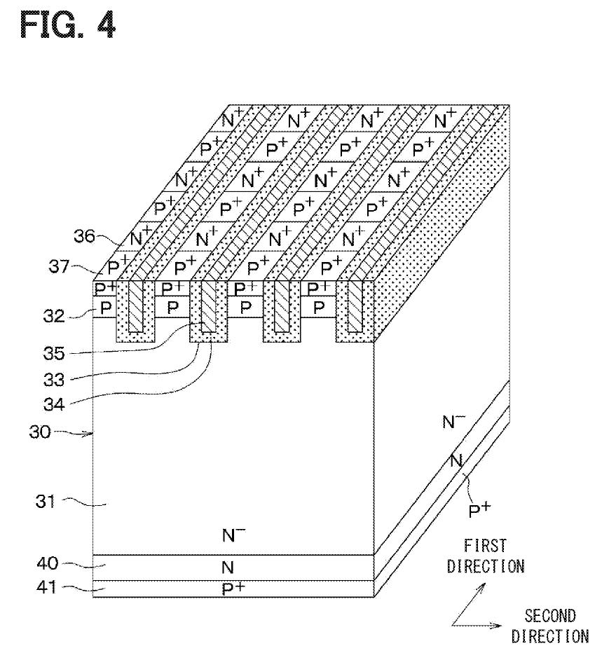

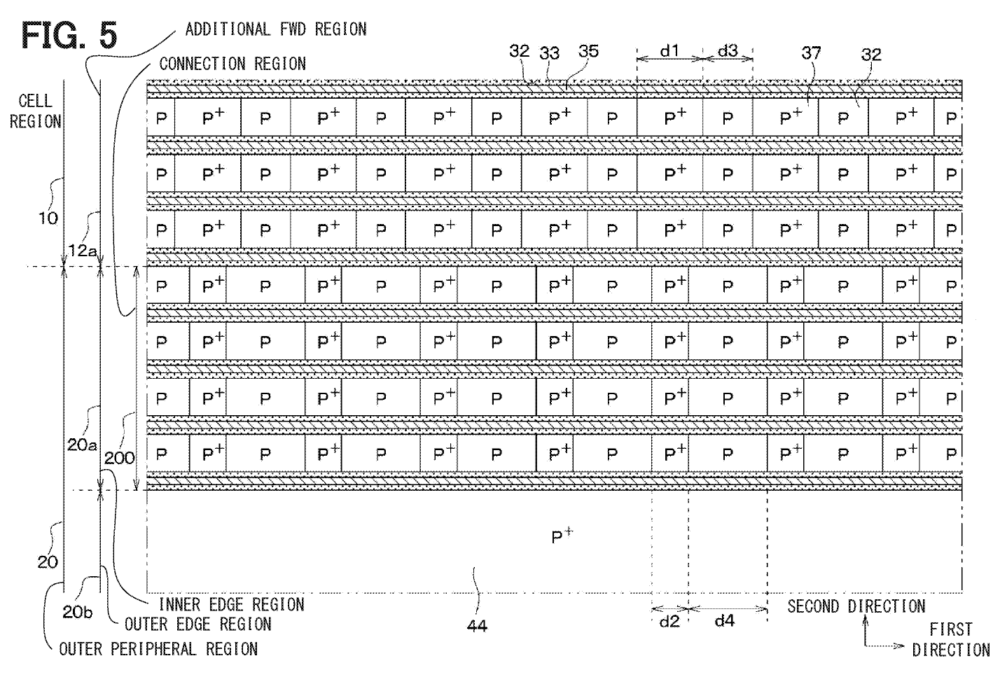

The above describes the planar configuration of the semiconductor device in the present embodiment. Next, the configuration of the semiconductor device will be described with reference to FIGS. 2 to 5. It should be noted that the additional FWD regions 12a have basically the same structure as the other FWD regions 12. Therefore, for example, in FIG. 3, the configuration of the additional FWD region 12a is shown as the configuration of the FWD region 12, but the configuration of the other FWD regions 12 is also the same as that of the additional FWD region 12a. In FIG. 4, an interlayer insulating film 38, an upper electrode 39, a lower electrode 43, and the like, which will be described later, are omitted from illustration. In addition, in FIG. 5, the interlayer insulating film 38 and the upper electrode 39, which will be described later, are omitted from illustration.

As shown in FIGS. 2 to 4, the semiconductor device includes the semiconductor substrate 30 that forms a drift layer 31 of N⁻-type. In the present embodiment, the semiconductor substrate 30 is formed of a silicon substrate. On the drift layer 31, a base layer 32 of P-type is formed in the connection regions 200 of the cell region 10 and the outer peripheral region 20. Hereinafter, a surface of the semiconductor substrate 30 on which the base layer 32 is formed will be referred to as a first surface 30a of the semiconductor substrate 30, and a surface opposite to the first surface 30a will be referred to as a second surface 30b.

A plurality of trenches 33 are provided in the semiconductor substrate 30 from the first surface 30a so as to penetrate through the base layer 32 and reach the drift layer 31. Accordingly, the base layer 32 is divided into multiple sections by the trenches 33. In the present embodiment, the trenches 33 are formed in each of the IGBT regions 11, the additional FWD regions 12a, and the connection regions 200. It should be noted that the trenches 33 formed in the outer peripheral region 20 are not formed below the pad portions 21 or the like, as shown in FIG. 2. In the present embodiment, the trenches 33 are formed in a stripe pattern with the first direction as the longitudinal direction.

Each of the trenches 33 is embedded with a gate insulating film 34 and a gate electrode 35. The gate insulating film 34 covers a wall surface of each of the trenches 33. The gate electrode 35 is formed of polysilicon or the like and is formed on the gate insulating film 34. Accordingly, a trench gate structure is formed.

The gate electrodes 35 disposed in the trenches 33 formed in the IGBT regions 11 are connected, via gate wiring (not shown), to one of the pad portions 21 shown in FIG. 1, so that a predetermined gate voltage can be applied. Furthermore, the gate electrodes 35 disposed in the trenches 33 formed in the additional FWD regions 12a (that is, the FWD regions 12) and the connection regions 200 are electrically connected to the upper electrode 39, which will be described later. In other words, the gate electrodes 35 in the additional FWD regions 12a and the connection regions 200 are maintained at a predetermined potential.

Emitter regions 36 of N⁺-type having a higher impurity concentration than the drift layer 31 are formed in a surface portion of the base layer 32 (that is, on a side adjacent to the first surface 30a of the semiconductor substrate 30) in the IGBT regions 11. Furthermore, contact regions 37 of P⁺-type having a higher impurity concentration than the base layer 32 are formed in the surface portion of the base layer 32 in the IGBT regions 11, the additional FWD regions 12a, and the connection regions 200.

In the present embodiment, as shown in FIG. 4, the emitter regions 36 and the contact regions 37 in the IGBT regions 11 are formed so as to be alternately arranged along the first direction between the trenches 33 that are adjacent in the second direction. Furthermore, the emitter regions 36 and the contact regions 37 in the IGBT regions 11 are each formed so as to be in contact with the trenches 33 that are adjacent in the second direction. Hereinafter, the trenches 33 that are adjacent in the second direction are simply referred to as adjacent trenches 33.

As shown in FIG. 5, the contact regions 37 in the additional FWD regions 12a and the connection regions 200 are formed so as to be scattered along the first direction. In addition, no emitter region 36 is disposed between the contact regions 37 that are adjacent in the first direction. Instead of the emitter region 36, the base layer 32 is arranged between the contact regions 37 that are adjacent in the first direction. That is, in the additional FWD regions 12a and the connection regions 200, between the adjacent trenches 33, the contact regions 37 and the base layer 32 are alternately arranged along the first direction.

The additional FWD regions 12a and the connection regions 200 are each formed so that the contact regions 37 have the following relationship. Specifically, the contact regions 37 are formed such that a formation area of the contact regions 37 per unit area in the connection regions 200 is smaller than a formation area of the contact regions per unit area in the additional FWD regions 12a. In other words, the contact regions 37 in the additional FWD regions 12a and the connection regions 200 are adjusted so that the proportion occupied by the contact regions 37 on the first surface 30a of the semiconductor substrate 30 located between the adjacent trenches 33 is as follows. Hereinafter, the proportion occupied by the contact regions 37 on the first surface 30a of the semiconductor substrate 30 between the adjacent trenches 33 will simply be referred to as the proportion occupied by the contact regions 37. That is, the proportion occupied by the contact regions 37 is set to be smaller in the connection regions 200 than in the additional FWD regions 12a. In other words, in the present embodiment, the area capable of forming ohmic contact with the upper electrode 39, which will be described later, is set to be larger in the additional FWD regions 12a than in the connection regions 200.

In the present embodiment, when the length along the first direction is defined as a width, a width d1 of the contact regions 37 in the additional FWD regions 12a is made wider than a width d2 of the contact regions 37 in the connection regions 200. In other words, a width d3 of the base layer 32 in the additional FWD regions 12a is set to be smaller than a width d4 of the base layer 32 in the connection regions 200.

As shown in FIG. 2 and FIG. 3, the interlayer insulating film 38 made of borophosphosilicate glass or the like is formed on the first surface 30a of the semiconductor substrate 30. Then, in the IGBT regions 11, contact holes 38a are formed in the interlayer insulating film 38 to expose the emitter regions 36 and the contact regions 37. In the interlayer insulating film 38, contact holes 38b are formed in the additional FWD regions 12a and the connection regions 200 to expose the contact regions 37 and the base layer 32. Furthermore, in the interlayer insulating film 38, contact holes 38c are formed in the additional FWD regions 12a and the outer peripheral region 20 to expose the gate electrodes 35. Additionally, in the interlayer insulating film 38, a contact hole 38d is formed in the outer peripheral region 20 to expose a deep layer 44, which will be described later.

Then, the upper electrode 39 is formed on the interlayer insulating film 38. Specifically, the upper electrode 39 is formed so as to be electrically connected to the emitter regions 36 and the contact regions 37 (that is, the base layer 32) in the IGBT regions 11 through the contact holes 38a formed in the interlayer insulating film 38. The upper electrode 39 is formed so as to be electrically connected to the base layer 32 and the contact regions 37 in the additional FWD regions 12a and the connection regions 200 through the contact holes 38b formed in the interlayer insulating film 38. In other words, on the interlayer insulating film 38, the upper electrode 39 is formed, which functions as an emitter electrode in the IGBT regions 11 and as an anode electrode in the additional FWD regions 12a (that is, the FWD regions 12). In addition, the upper electrode 39 is formed so as to be electrically connected to the gate electrodes 35 in the additional FWD regions 12a and the connection regions 200 through the contact holes 38c formed in the interlayer insulating film 38. As a result, the gate electrodes 35 formed in the additional FWD regions 12a and the connection regions 200 are maintained at the same potential as the upper electrode 39. In addition, the upper electrode 39 is formed so as to be electrically connected to the deep layer 44, which will be described later, in the outer peripheral region 20 through the contact hole 38d formed in the interlayer insulating film 38.

On a side of the drift layer 31 opposite to the base layer 32 (that is, on a side of the drift layer 31 close to the second surface 30b of the semiconductor substrate 30), a field stop layer (hereinafter referred to as an FS layer) 40 of N-type having a higher impurity concentration than the drift layer 31 is formed.

Then, in the IGBT regions 11, a collector layer 41 of P⁺-type is formed on the opposite side of the drift layer 31 across the FS layer 40, and in the additional FWD regions 12a, a cathode layer 42 of N⁺-type is formed on the opposite side of the drift layer 31 across the FS layer 40. In other words, the IGBT regions 11 and the additional FWD regions 12a (that is, the FWD regions 12) are distinguished by whether the layer formed on the second surface 30b of the semiconductor substrate 30 is the collector layer 41 or the cathode layer 42. In the outer peripheral region 20, the collector layer 41 is formed on the side opposite to the drift layer 31 across the FS layer 40.

On the side opposite to the drift layer 31, across the collector layer 41 and the cathode layer 42 (that is, on the second surface 30b of the semiconductor substrate 30), a lower electrode 43 electrically connected to the collector layer 41 and the cathode layer 42 is formed. The lower electrode 43 functions as a collector electrode in the IGBT regions 11 and as a cathode electrode in the additional FWD regions 12a. Furthermore, the lower electrode 43 is also connected to the collector layer 41 in the outer peripheral region 20.

Thus, with the above configuration, in the additional FWD regions 12a (that is, the FWD regions 12), FWD elements are formed by a PN junction in which the base layer 32 and the contact regions 37 serve as the anode, and the drift layer 31, the FS layer 40, and the cathode layer 42 serve as the cathode.

The connection regions 200 of the outer peripheral region 20 have, as described above, substantially the same basic structure as the additional FWD regions 12a at a portion adjacent to the first surface 30a, with the collector layer 41 disposed on the second surface 30b. However, as described above, in the connection regions 200, the formation area of the contact regions 37 per unit area is set to be smaller than the formation area of the contact regions 37 per unit area in the additional FWD regions 12a.

In the outer edge region 20b of the outer peripheral region 20, the deep layer 44 of P⁺-type is formed. The deep layer 44 is connected to the base layer 32, and has a higher impurity concentration than the base layer 32. In the present embodiment, the deep layer 44 is formed deeper than the base layer 32, extends to a portion beneath the pad portions 21 in the inner edge region 20a and is connected to the base layer 32. The deep layer 44 is formed in a frame shape so as to surround the inner edge region 20a.

In addition, although not specifically illustrated, a guard ring or the like is also appropriately formed in the outer peripheral region 20 so as to surround the deep layer 44. The guard ring, for example, is configured as a multiple ring structure formed in a plurality so as to surround the deep layer 44.

Above the first surface 30a of the semiconductor substrate 30, a protective film 45 made of polyimide or the like is formed. The protective film 45 is formed with contact holes 45a for exposing the upper electrodes 39 in the cell regions 10, and a contact hole 45b for exposing the pad portions 21 in the outer peripheral region 20. The contact holes 45a are, for example, formed in a substantially rectangular shape corresponding to the cell regions 10. In this case, since the additional FWD regions 12a are portions arranged in addition to the substantially rectangular cell regions 10, most portions of the additional FWD regions 12a are covered by the protective film 45.

The above describes the configuration of the semiconductor device in the present embodiment. In the present embodiment, the N-type, the N⁺-type, and the N⁻-type correspond to a first conductive type, and the P-type and P⁺-type correspond to a second conductive type. Furthermore, in the present embodiment, since the semiconductor device is configured as described above, the semiconductor substrate 30 includes components such as the collector layer 41, the cathode layer 42, the drift layer 31, the base layer 32, the emitter regions 36, and the contact regions 37.

Next, while explaining the operation of the semiconductor device, the detailed configuration of the semiconductor device will be further described.

In the semiconductor device as described above, when a voltage higher than that of the upper electrode 39 is applied to the lower electrode 43, the PN junction formed between the base layer 32 and the drift layer 31 enters a reverse conduction state, thereby forming a depletion layer. Then, when a low-level gate voltage (for example, 0 V) that is less than a threshold voltage Vth of the insulated gate structure is applied to the gate electrodes 35, no current flows between the upper electrode 39 and the lower electrode 43.

To turn the IGBT elements on, a high-level gate voltage equal to or greater than the threshold voltage Vth of the insulated gate structure is applied to the gate electrodes 35 of the IGBT regions 11, while a voltage higher than that of the upper electrode 39 is applied to the lower electrode 43. As a result, in the IGBT regions 11, inversion layers are formed in portions of the base layer 32 that are in contact with the trenches 33 where the gate electrodes 35 are disposed. Then, in the IGBT elements, electrons are supplied from the emitter regions 36 to the drift layer 31 via the inversion layers, thereby holes are supplied from the collector layer 41 to the drift layer 31. As a result of this conductivity modulation, the resistance value of the drift layer 31 decreases. As a result, current flows between the upper electrode 39 and the lower electrode 43 in the IGBT elements.

When the IGBT elements are turned to the OFF state and the FWD elements are turned to the ON state (that is, the FWD elements are operated as diodes), the voltages to be applied to the upper electrode 39 and the lower electrode 43 are switched, and a voltage higher than that applied to the lower electrode 43 is applied to the upper electrode 39. As a result, holes are supplied to the base layer 32 and electrons are supplied to the cathode layer 42, causing the FWD elements to operate as the diodes.

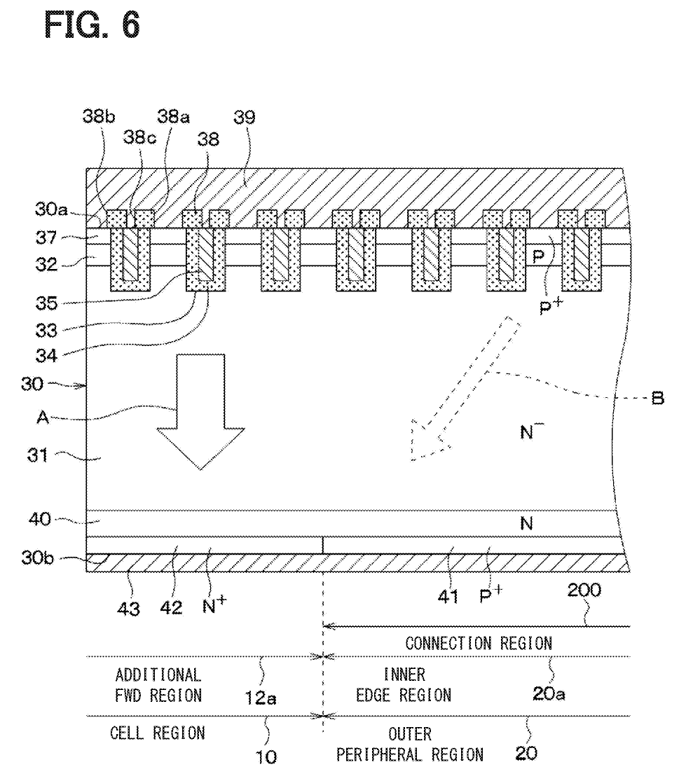

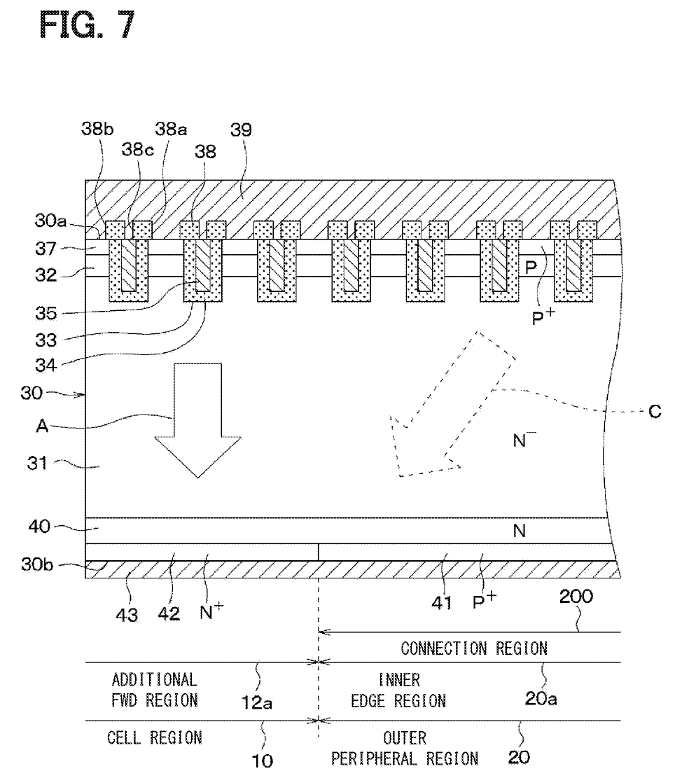

At this time, in the connection regions 200, as described above, the contact regions 37 are formed on the first surface 30a of the semiconductor substrate 30. When the FWD elements are turned on, holes are supplied to the base layer 32 via the contact regions 37. However, in the present embodiment, the formation area of the contact regions 37 per unit area in the connection regions 200 of the outer peripheral region 20 is set to be smaller than the formation area of the contact regions 37 per unit area in the additional FWD regions 12a. Therefore, when the FWD elements are in the ON state, as shown in FIG. 6 and FIG. 7, the amount of holes supplied from the connection regions 200 of the outer peripheral region 20 to the additional FWD regions 12a can be reduced.

FIG. 6 shows the flow of holes when the FWD elements in the semiconductor device according to the present embodiment are in the ON state, and FIG. 7 shows the flow of holes when the FWD elements in a semiconductor device of a comparative example are in the ON state. The semiconductor device of the comparative example has a configuration similar to the above-described configuration of the semiconductor device according to the present embodiment except that a formation area of the contact regions 37 per unit area in the connection regions 200 and a formation area of the contact regions 37 per unit area in the additional FWD regions 12a are set to be equal to each other. The arrows A and B in FIG. 6, and the arrows A and C in FIG. 7, indicate the flow of holes.

Subsequently, when switching the FWD elements from the ON state to the OFF state, a reverse voltage is applied by applying a voltage to the lower electrode 43 that is higher than that applied to the upper electrode 39. That is, when interrupting the forward current flowing through the FWD elements, a reverse voltage is applied by applying a voltage to the lower electrode 43 that is higher than that applied to the upper electrode 39. As a result, the FWD elements turn to the recovery state.

At this time, in the present embodiment, as described above, the supply of holes from the connection regions 200 in the outer peripheral region 20 to the additional FWD regions 12a is suppressed while the FWD elements are in the ON state. Therefore, a recovery current can be reduced, and a recovery loss Err can be reduced.

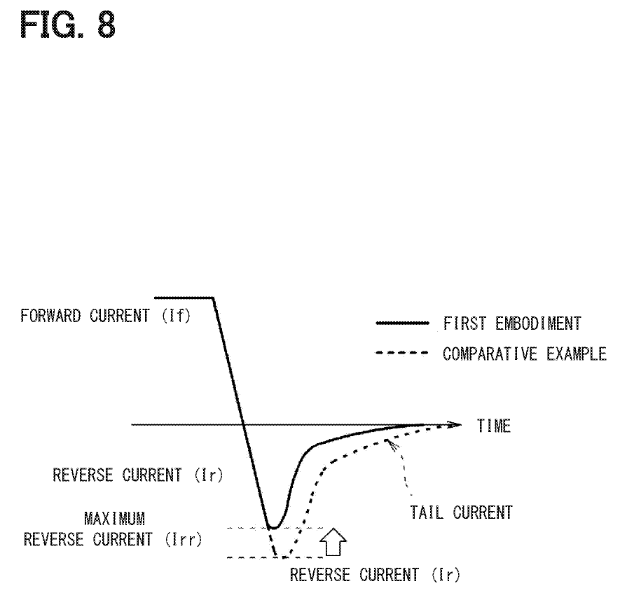

Specifically, as a result of investigations conducted by the inventors, the results shown in FIG. 8 were obtained. As shown in FIG. 8, it was confirmed that, in the semiconductor device of the present embodiment, both a maximum reverse current Irr and a tail current can be reduced compared to the semiconductor device of the comparative example. Then, since the integral value of the reverse current Ir in FIG. 8, that is, the area of the region where the current value becomes negative, corresponds to the recovery loss Err, it is confirmed that by reducing the maximum reverse current Irr, the recovery loss Err can also be reduced.

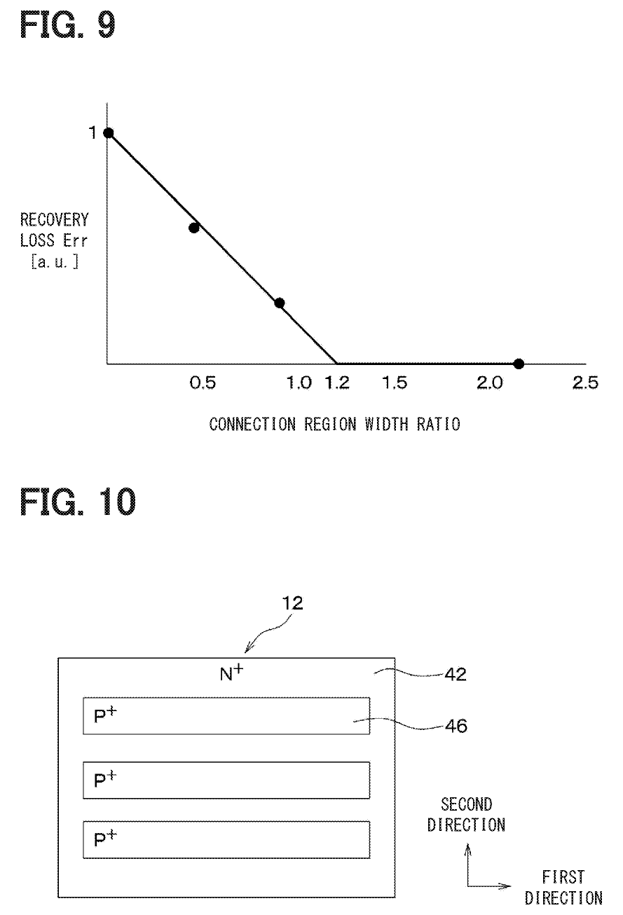

In addition, the inventors diligently investigated the width of the connection regions 200 and obtained the results shown in FIG. 9. Note that FIG. 9 shows the ratio of the width La of the connection regions 200 to the thickness of the semiconductor substrate 30 as the connection region width ratio. The width La of the connection regions 200 refers to the length, along the second direction, of the region where the formation area of the contact regions 37 per unit area is smaller than the formation area of the contact regions 37 per unit area in the additional FWD regions 12a. In the present embodiment, since the entire region between the additional FWD regions 12a and the deep layer 44 is defined as the connection regions 200, a width La of the connection regions 200 is the length along the second direction between the additional FWD regions 12a and the deep layer 44, as shown in FIG. 1. Further, the thickness of the semiconductor substrate 30 refers to the length between the first surface 30a and the second surface 30b of the semiconductor substrate 30.

As shown in FIG. 9, it is confirmed that the recovery loss Err gradually decreases as the connection region width ratio increases, within the range where the connection region width ratio is less than 1.2. Then, the recovery loss Err remains almost unchanged when the connection region width ratio is 1.2 or greater. Therefore, it is preferable that the semiconductor device has a connection region width ratio of 1.2 or greater.

It should be noted that although the magnitude of the recovery loss Err changes when the formation area of the contact regions 37 in the connection regions 200 is varied, the relationship between the recovery loss Err and the connection region width ratio does not change. In other words, if the formation area of the contact regions 37 per unit area of the connection regions 200 is smaller than the formation area of the contact regions 37 per unit area of the additional FWD region 12a, the specific values of each formation area can be changed as appropriate. However, regardless of the formation area, it is preferable that the connection region width ratio is 1.2 or greater.

The above description is the operation of the semiconductor device according to the present embodiment. The semiconductor device can be used, for example, in the following manner. That is, the semiconductor device is used in such a manner that a nickel plating film or the like is disposed on the portion of the upper electrode 39 exposed through an opening in the protective film 45, and another electrode or the like is disposed above the nickel plating film via solder or the like. In this case, by making the contact hole 45a formed in the protective film 45 substantially rectangular in planar shape, it becomes easier to suppress the spreading of solder disposed on the nickel plating film. Therefore, in the present embodiment, the contact hole 45a is formed in a substantially rectangular planar shape, and most of the additional FWD regions 12a are covered by the protective film 45.

However, with such a configuration, since the protective film 45 is disposed over the additional FWD regions 12a, there is a concern that the heat dissipation of the additional FWD regions 12a may deteriorate. According to the investigations by the present inventors, when considering heat dissipation, it was confirmed that when the width between the additional FWD regions 12a and the outer edge region 20b (that is, the deep layer 44) is at least about twice the thickness of the semiconductor substrate 30, heat dissipation can be prevented from deteriorating. Therefore, in cases where the additional FWD regions 12a of the semiconductor device may become highly heated during use, it is preferable that the width between the additional FWD regions 12a and the outer edge region 20b is at least about twice the thickness of the semiconductor substrate 30. In the present embodiment, since only the connection regions 200 are disposed between the additional FWD regions 12a and the outer edge region 20b, the width between the additional FWD regions 12a and the outer edge region 20b is the width La of the connection regions 200.

According to the present embodiment described above, the connection regions 200 are configured such that the formation area of the contact regions 37 per unit area is smaller than the formation area of the contact regions 37 per unit area in the additional FWD regions 12a. Therefore, even in a semiconductor device having the additional FWD regions 12a, an increase in recovery loss Err can be suppressed.

In the present embodiment, the connection region width ratio is set to 1.2 or greater. Therefore, an increase in recovery loss Err can be sufficiently suppressed.

### Second Embodiment

The following describes a second embodiment of the present disclosure. The present embodiment differs from the first embodiment in that suppression layers are added to the FWD regions 12. The other configurations of the present embodiment are similar to those of the first embodiment, and therefore a description of the similar configurations will be omitted.

In the semiconductor device of the present embodiment, as shown in FIG. 10, a plurality of suppression layers 46 is formed within the cathode layer 42 on the second surface 30b in the FWD regions 12. In the present embodiment, the suppression layers 46 are of P⁺-type and have the same impurity concentration as the collector layer 41. Additionally, although not specifically shown in the figures, the suppression layers 46 have the same depth as the collector layer 41. Furthermore, in the present embodiment, the suppression layers 46 extend along the second direction. It should be noted that such suppression layers 46 are formed simultaneously when the collector layer 41 is formed.

According to the present embodiment described above, the connection regions 200 are configured such that the formation area of the contact regions 37 per unit area is smaller than the formation area of the contact regions 37 per unit area in the additional FWD regions 12a. Therefore, the same effects as those of the first embodiment described above can be obtained.

In the present embodiment, the suppression layers 46 are formed within the cathode layer 42. Therefore, when the FWD elements are in the ON state, if holes injected from the upper electrode 39 reach the suppression layers 46, they can be rendered inactive carriers, and the injection of electrons from the lower electrode 43 can be suppressed. Accordingly, further reduction of the recovery loss Err can be achieved.

### Modifications of Second Embodiment

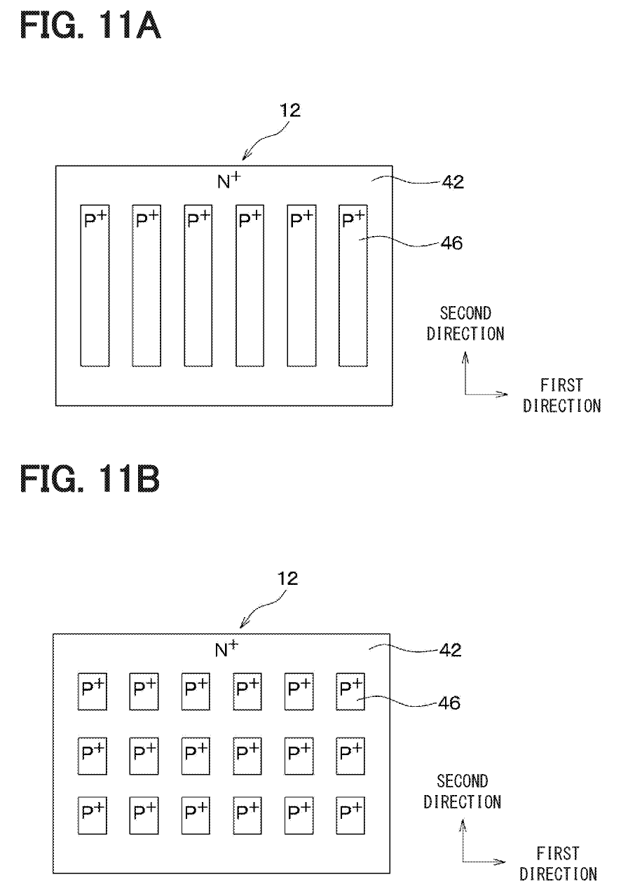

Modifications of the second embodiment will be described below. In a modification, the suppression layers 46 may extend along the first direction, as shown in FIG. 11A. In another modification, the suppression layers 46 may be distributed in a scattered manner along the first and second directions, as shown in FIG. 11B. In other words, the suppression layers 46 may be extended along the first direction or the second direction, and the extended portions may be formed in a shape divided into a plurality of segments. Furthermore, in other words, the suppression layers 46 may be formed so that the cathode layer 42 has a lattice structure.

The suppression layers 46 may have any configuration as long as they can suppress the injection of electrons from the lower electrode 43 when the FWD elements are in the ON state. Therefore, the suppression layers 46 may be of N-type having a lower impurity concentration than the cathode layer 42.

### Third Embodiment

The following describes a third embodiment of the present disclosure. The present embodiment differs from the first embodiment in that the width of the additional FWD regions 12a and the width of the other FWD regions 12 have been changed. The other configurations of the present embodiment are similar to those of the first embodiment, and therefore a description of the similar configurations will be omitted.

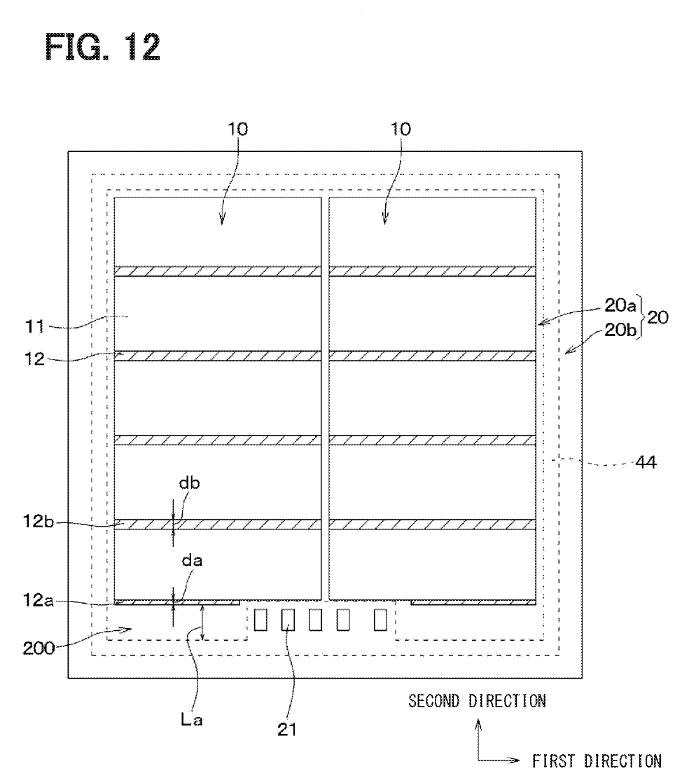

First, in the present embodiment, as shown in FIG. 12, among the FWD regions 12, the FWD regions 12 that are different from the additional FWD regions 12a are defined as inner FWD regions 12b. In other words, among the FWD regions 12, the FWD regions 12 that are sandwiched by the IGBT regions 11 in the second direction are defined as the inner FWD regions 12b.

Then, in the semiconductor device of the present embodiment, when the lengths of the additional FWD regions 12a and the inner FWD regions 12b along the second direction are defined as a width da and a width db, respectively, the width da of the additional FWD regions 12a is set to be smaller than the width db of the inner FWD regions 12b. In other words, the additional FWD regions 12a are configured to allow less current to flow compared to the inner FWD regions 12b.

According to the present embodiment described above, the connection regions 200 are configured such that the formation area of the contact regions 37 per unit area is smaller than the formation area of the contact regions 37 per unit area in the additional FWD regions 12a. Therefore, the same effects as those of the first embodiment can be obtained.

As described in the first embodiment above, since the protective film 45 is disposed over the additional FWD regions 12a, the additional FWD regions 12a are more likely to have lower heat dissipation compared to the inner FWD regions 12b. Therefore, in the present embodiment, the width da of the additional FWD regions 12a is set to be smaller than the width db of the inner FWD regions 12b, so that the additional FWD regions 12a allow less current to flow compared to the inner FWD regions 12b. In other words, the additional FWD regions 12a are made less likely to generate heat than the inner FWD regions 12b. Therefore, it is possible to suppress the additional FWD regions 12a from reaching a high temperature and being damaged.

### Fourth Embodiment

The following describes a fourth embodiment. In the present embodiment, connecting regions are disposed between the additional FWD regions and the IGBT regions, as compared with the first embodiment. The other configurations of the present embodiment are similar to those of the first embodiment, and therefore a description of the similar configurations will be omitted.

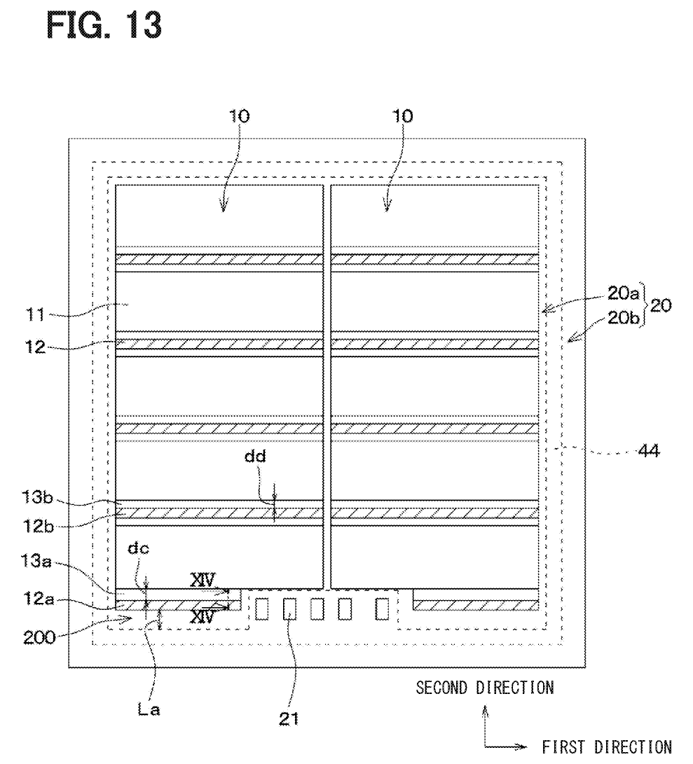

As shown in FIG. 13, in the semiconductor device of the present embodiment, connecting regions 13a and 13b are disposed between the FWD regions 12 and the IGBT regions 11. Hereinafter, the connecting regions disposed between the additional FWD regions 12a and the IGBT regions 11 are referred to as first connecting regions 13a, and the connecting regions disposed between the other FWD regions 12 and the IGBT regions 11 are referred to as second connecting regions 13b.

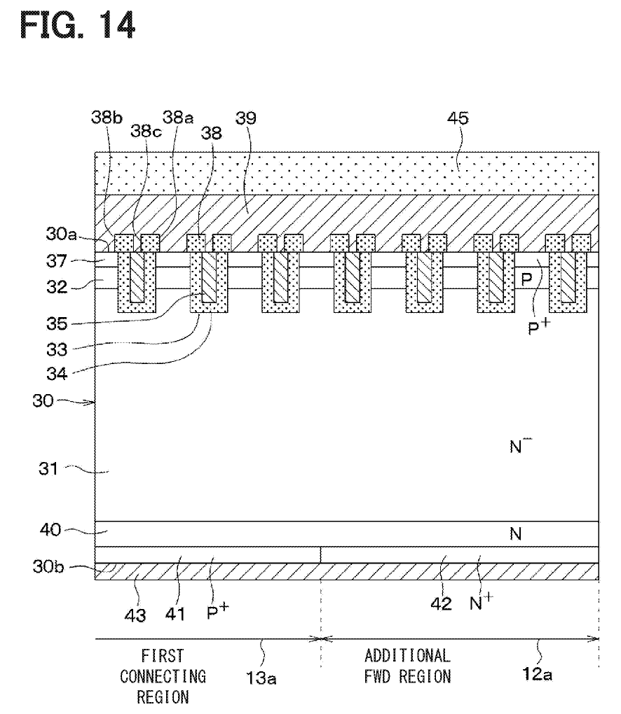

As shown in FIG. 14, in the first connecting regions 13a, portions adjacent to the first surface 30a of the semiconductor substrate 30 have the same configurations as those of the connection regions 200, and the collector layer 41 is disposed on the second surface 30b of the semiconductor substrate 30. That is, in the first connecting regions 13a, the formation area of the contact regions 37 per unit area is set to be smaller than the formation area of the contact regions 37 per unit area in the IGBT regions 11. Although the configurations of the second connecting regions 13b are not specifically illustrated, they have the same configuration as the first connecting regions 13a.

Furthermore, as described above, the contact holes 45a are formed in substantially rectangular shapes to match the cell regions 10. Therefore, the first connecting regions 13a, like the additional FWD regions 12a, are mostly covered by the protective film 45.

Then, when the lengths of the first and second connecting regions 13a and 13b along the second direction are defined as a width dc and a width dd, respectively, the width dc of the first connecting regions 13a is set to be wider than the width dd of the second connecting regions 13b.

According to the present embodiment described above, the connection regions 200 are configured such that the formation area of the contact regions 37 per unit area is smaller than the formation area of the contact regions 37 per unit area in the additional FWD regions 12a. Therefore, the same effects as those of the first embodiment can be obtained.

In the present embodiment, first and second connecting regions 13a and 13b are disposed between the FWD regions 12 and the IGBT regions 11. Therefore, when the FWD elements are in the ON state, injection of holes from the IGBT regions 11 into the FWD regions 12 can be suppressed. In addition, in the first connecting regions 13a and the second connecting regions 13b, the formation area of the contact regions 37 per unit area is set to be smaller than the formation area of the contact regions 37 per unit area in the IGBT regions 11. Therefore, when the FWD elements are in the ON state, compared to the case where the FWD regions 12 and the IGBT regions 11 are in direct contact, the amount of holes supplied to the FWD regions 12 from the first connecting regions 13a and the second connecting regions 13b can be reduced. Accordingly, the recovery loss Err can be further reduced.

Furthermore, in the present embodiment, the width dc of the first connecting regions 13a is set to be wider than the width dd of the second connecting regions 13b. Therefore, when the FWD elements are in the ON state, compared to the case where the width dc of the first connecting regions 13a and the width dd of the second connecting regions 13b are the same, the injection of holes from the IGBT regions 11 into the additional FWD regions 12a can be further suppressed. Accordingly, the recovery loss Err can be further reduced.

It is also possible to apply the same gate voltage to the gate electrodes 35 in the first connecting regions 13a and the second connecting regions 13b as is applied to the gate electrodes 35 in the IGBT regions 11. According to this configuration, when the IGBT elements are in the ON state, channels are also formed on the sidewalls of the trenches 33 in the first connecting regions 13a and the second connecting regions 13b, and thus, the increase in ON-resistance due to the arrangement of the first connecting regions 13a and the second connecting regions 13b can be suppressed.

### Other Embodiments

Although the present disclosure has been described in accordance with the embodiments, it is understood that the present disclosure is not limited to such embodiments or structures. The present disclosure encompasses various modifications and variations within the scope of equivalents. Furthermore, various combinations and formations, and other combinations and formations including one, more than one or less than one element may be made in the present disclosure.

For example, in each of the above-described embodiments, the example is described in which the first conductive type is N-type and the second conductive type is P-type. Alternatively, the first conductive type may be P-type and the second conductive type may be N-type.

Furthermore, in each of the above-described embodiments, the gate electrode 35 of the FWD region 12 and the gate electrode 35 of the connection region 200 may be connected to another electrode instead of the upper electrode 39 so that their potential is maintained.

In addition, in each of the above embodiments, emitter regions 36 similar to those in the IGBT regions 11 may also be formed in the FWD regions 12 and the connection regions 200.

Furthermore, in each of the above-described embodiments, the cell region 10 may be a single region or may be three or more regions.

Furthermore, in each of the above-described embodiments, the pad portions 21 may be collectively arranged at one end portion in the first direction at the one end portion in the second direction. The additional FWD region 12a may be disposed only in one of the cell regions 10 among the cell regions 10 that are adjacent to each other in the first direction.

Furthermore, in each of the above-described embodiments, if the formation area of the contact regions 37 per unit area in the connection regions 200 is smaller than the formation area of the contact regions 37 per unit area in the additional FWD region 12a, the detailed configuration may be appropriately modified. For example, the width d1 of the contact regions 37 in the additional FWD regions 12a and the width d2 of the contact regions 37 in the connection regions 200 may be set to be equal, but the contact regions 37 in the connection regions 200 may also be formed with some contacts omitted. In other words, the width d1 of the contact regions 37 in the additional FWD regions 12a and the width d2 of the contact regions 37 in the connection regions 200 may be set to be equal, but the width d4 of the base layer 32 in the connection regions 200 may also be set to be wider than the width d3 of the base layer 32 in the additional FWD regions 12a.

Furthermore, in each of the above-described embodiments, the connection region width ratio may be less than 1.2.

Additionally, in each of the above-described embodiments, another region may be disposed between the connection regions 200 and the outer edge region 20b. For example, an intermediate region may also be provided. The intermediate region has a configuration in which a portion adjacent to the first surface 30a of the semiconductor substrate 30 has the same configuration as that of the additional FWD regions 12a, and the collector layer 41 is disposed on the second surface 30b. In this case, if the connection region width ratio is set to 1.2 or more, the formation area of the contact regions in the intermediate region is not particularly limited and, for example, may be equal to or greater than the formation area of the contact regions in the additional FWD regions 12a. In other words, the connection regions 200 are regions disposed between the additional FWD regions 12a and the outer edge region 20b, and can be described as regions in which the formation area of the contact regions 37 per unit area is smaller than that in the additional FWD regions 12a.

Furthermore, it is also possible to provide a semiconductor device that appropriately combines the various embodiments. For example, the second embodiment may be combined with the third or the fourth embodiment so that suppression layers 46 are disposed within the cathode layer 42. In another example, the third embodiment may be combined with the fourth embodiment so that the width da of the additional FWD regions 12a is smaller than the width db of the inner FWD regions 12b. Combinations of the above-described embodiments may be further combined.

What is claimed is:

1. A semiconductor device comprising:
a semiconductor substrate having a cell region and an outer peripheral region surrounding the cell region;
insulated gate bipolar transistor (IGBT) regions disposed in the cell region and having IGBT elements; and
free-wheel diode (FWD) regions disposed in the cell region and having FWD elements, wherein
the IGBT regions and the FWD regions are alternately arranged along one direction in a planar direction of the semiconductor substrate,
the outer peripheral region includes a pad portion electrically connected to the IGBT elements, the pad portion being disposed at one end portion of the outer peripheral region in the one direction,
the cell region includes, as the FWD regions, an inner FWD region sandwiched between the IGBT regions and an additional FWD region disposed on one side in an intersecting direction, which intersects with the one direction in the planar direction of the semiconductor substrate, relative to the pad portion, and an end portion of the cell region adjacent to the pad portion in the one direction includes the additional FWD region,
the outer peripheral region includes an inner edge region adjacent to the cell region and an outer edge region located opposite to the cell region across the inner edge region,
the inner edge region includes a connection region located between the additional FWD region and the outer edge region,
the semiconductor substrate includes:
a drift layer of a first conductivity type disposed in the cell region and the connection region;
a base layer of a second conductivity type disposed in a surface portion of the drift layer in the cell region and the connection region;
a collector layer of the second conductivity type disposed on a side of the drift layer opposite to the base layer in the IGBT regions and the connection region; and
a cathode layer of the first conductivity type disposed on the side of the drift layer opposite to the base layer in the FWD regions,
a surface of the semiconductor substrate adjacent to the base layer is defined as a first surface, and a surface of the semiconductor substrate adjacent to the collector layer and the cathode layer is defined as a second surface,
the semiconductor device further comprises:
a trench gate structure provided in the IGBT regions, the FWD regions, and the connection region, and including trenches extending deeper than the base layer into the drift layer, and a gate insulating film and a gate electrode disposed in the trenches;
an emitter region of the first conductivity type disposed in a surface portion of the base layer in the IGBT regions, in contact with the trenches; and
a contact region of the second conductivity type disposed in the surface portion of the base layer in the additional FWD region and the connection region and having a higher impurity concentration than the base layer, and
wherein on the first surface of the semiconductor substrate, a formation area of the contact region per unit area in the connection region is smaller than a formation area of the contact region per unit area in the additional FWD region.

2. The semiconductor device according to claim 1, wherein
a ratio of a width of the connection region along the one direction to a thickness of the semiconductor substrate is 1.2 or greater.

3. The semiconductor device according to claim 1, wherein
each of the FWD regions includes a suppression layer within the cathode layer, and
the suppression layer is of the second conductivity type, or is of the first conductivity type and has a lower impurity concentration than the cathode layer.

4. The semiconductor device according to claim 1, wherein
among the FWD regions, a width of the additional FWD region along the one direction is smaller than a width of the inner FWD region along the one direction.

5. The semiconductor device according to claim 1, further comprising
connecting regions disposed between the FWD regions and the IGBT regions, wherein
each of the connecting regions includes the base layer disposed in the surface portion of the drift layer and the contact region disposed in the surface portion of the base layer,
on the first surface of the semiconductor substrate, a formation area of the contact region per unit area in the connecting regions is smaller than a formation area of the contact region per unit area in the IGBT regions,
the connecting regions include a first connecting region disposed between the additional FWD region and an adjacent one of the IGBT regions, and a second connecting region disposed between the inner FWD region and an adjacent one of the IGBT regions, and
a width of the first connecting region along the one direction is greater than a width of the second connecting region along the one direction.
